(19) United States
(12) Patent Application Publication
(10) Pub. No.: US 2008/0049479 A1
(43) Pub. Date: Feb. 28, 2008

(54) COMBINED MODULATOR AND INVERTER

(76) Inventors: Mervin A. Dayan, Oakhurst, NJ (US); Maurice S. Dayan, Oakhurst, NJ (US)

Correspondence Address: WOLF, BLOCK, SCHORR & SOLIS-COHEN LLP, 1650 ARCH STREET, 22ND FLOOR, PHILADELPHIA, PA, 19103-2334, US

(21) Appl. No.: 11/757,774

(22) Filed: Jun. 4, 2007

Related U.S. Application Data
(63) Continuation of application No. 11/681,988, filed on Mar. 5, 2007.
(60) Provisional application No. 60/828,293, filed on Oct. 5, 2006.
(60) Provisional application No. 60/778,661, filed on Mar. 3, 2006.

(51) Int. Cl. H02M 1/00; H04B 1/034; H05K 9/00

(52) U.S. Cl. 363/146; 361/818; 455/128

(57) ABSTRACT

A combined modulator and inverter for use in transmitting audio files to a receiver. The combined modulator and inverter enables the usage of various devices in a vehicle that utilize different types of power sources. Audio devices may be used with the modulator and inverter to play the devices over a radio. The device may also have the ability to play audio files received from devices enabled to store digital flies.

This application claims benefit of U.S. Provisional Application No. 60/828,293 filed on Oct. 5, 2006; U.S. Provisional Application No. 60/778,661 filed on Mar. 3, 2006; and U.S. Non Provisional application Ser. No. 11/681,988 filed on Mar. 5, 2007.

### FIELD OF THE INVENTION

The invention relates generally to the field of modulators and inverters, and specifically to a combined modulator and inverter for audio transmission.

### BACKGROUND OF THE INVENTION

Many audio and video products are portable. DVD-players, CD-players, cassette players, laptops, stereos, televisions and MP3 players are just a few examples of these products. Some portable audio and video products contain speakers or headphone jacks. However, when traveling in a car or at home, the user may prefer to have better sound quality or have the sound outputted from an element different from the portable unit itself, such as a home or automobile stereo.

Modulators are used to wirelessly connect a portable audio and/or video player to a home or automobile stereo. The portable audio and/or video player is first coupled to the modulator with an audio/video jack or other connection. The modulator is powered by plugging it into a standard wall socket or other source of electrical energy. During operation, the portable audio and/or video player decodes the data files stored on its internal memory and transmits the decoded data to the modulator via the connection in a signal format. The modulator then converts the signal that it receives from the portable audio and/or video player into a radio frequency signal and transmits the RF signal for receipt by the tuner of the desired stereo system. While functional, this existing system and mode of operation suffers from a number of deficiencies.

First, existing modulators are not specifically suited for use in automobiles, requiring a separate power adapter that is compatible with a power source, such as a cigarette lighter. As such, the user must have three separate components to achieve their goal, the modulator, the audio/video player, and the specialized socket power adapter, not too mention all of the necessary connection cables/wires.

Existing modulators cannot function without the audio/video player because they do not have the capability to actually read, process, and/or decompress the data format in which audio and/or video content is stored. Thus, for example, a separate MP3 player, DVD player, and/or CD player is required in addition to the modulator. In such systems, the modulator merely acts an intermediary between the MP3 player, DVD player, and/or CD player and the ear stereo system. The modulator cannot be simply coupled to an external memory device, such as a CD, disk, USB memory device, etc, that contains the desired audio and/or video data files. This is inconvenient for users that typically store their desired content on portable memory devices.

When the user desires to output audio/video content within an automobile, most automobiles have only one source of electrical power, a single cigarette lighter socket. However, because both the modulator and audio/video player require a power source, one of the devices must be powered by a battery. This is undesirable because batteries ran out and can be expensive to replace or timely to charge.

Finally, existing FM modulators currently permit only one type of output port or jack (RCA jacks, firewire or miniplugs) to be used to connect the portable device to the modulators. Many also require additional connections such as cassettes or docking stations. This means modulators are not available for devices that do not use these types of electrical connections. Furthermore, different devices having different output ports or jacks from one another require different modulators because the output mechanisms are not the same, i.e., if an MP3 player has a firewire output and a CD-player has a miniplug output, two different modulators are needed.

Additionally, with the multitude of portable electronic devices that are on the market, there is frequently a need for having the capacity to supply power to multiple devices while in a vehicle.

Thus, there is a need for an apparatus that does not suffer from the aforementioned drawbacks.

### SUMMARY OF THE INVENTION

It is therefore an object of the present invention to provide a combined modulator and inverter.

Another object of the present invention is to provide a combined modulator and inverter apparatus that can be used in a vehicle.

Yet another object of the present invention is to provide a combined modulator and inverter that minimized and/or eliminates interference present in the RF signal generated by the modulator.

Yet another object of the invention may be to provide multiple power sources for a variety of devices.

Yet another object of the invention may be to reproduce transmit audio signals from a variety of devices to stereo systems located within vehicles.

Yet another object of the invention is may be to minimize the number of devices needed to charge external devices in a vehicle.

Yet another object of the invention may be to convert information received, from external storage devices into RF signals.

These and other objects are met by the present invention, which in one embodiment is a combined modulator and power inverter apparatus comprising: a power plug for operable insertion into a cigarette lighter power receptacle of an automobile; a housing comprising a port, adapted to operably receive an external electronic device, a direct current power receptacle, an alternating current power receptacle and a radio frequency transmitter; a circuit positioned within the housing, the circuit operably connected to the power plug, the port, the direct current power receptacle, the alternating current power receptacle and the radio frequency transmitter; and the circuit adapted to (i) convert audio data signals received by the port into corresponding radio frequency signals; (ii) transmit the corresponding radio frequency signals to a receiver of the automobile via the radio frequency transmitter; (iii) supply direct current power from the power plug to the direct current receptacle; and (iv) convert direct current power from the power plug into alternating current power and supply the alternating current power to the alternating current receptacle.

A second aspect of the invention is a combined modulator and power inverter apparatus comprising: a power plug for operable insertion into a cigarette lighter power receptacle of an automobile; a housing comprising a port adapted to operably receive an external electronic device, a direct current power receptacle, an alternating current power receptacle and a radio frequency transmitter; a circuit positioned within the housing, the circuit operably connected to the power plug, the port, the direct current power receptacle, the alternating current power receptacle and the radio frequency transmitter; the circuit adapted to (i) convert audio data signals received by the port into corresponding radio frequency signals: (ii) transmit the corresponding radio frequency signals to a receiver of the automobile via the radio frequency transmitter; (iii) supply direct current power from the power plug to the direct current receptacle; and (iv) convert direct current power from, the power plug into alternating current power and supply the alternating current power to the alternating current receptacle; and means for shielding the radio frequency transmitter from electromagnetic interference generated by the circuit.

These and various other advantages and features of novelty that characterize the invention are pointed out with particularity in the claims annexed hereto and forming a part hereof. However, for a better understanding of the invention, its advantages, and the objects obtained by its use, reference should be made to the drawings which form a further part hereof, and to the accompanying descriptive matter, in which there is illustrated and described a preferred embodiment of the invention.

### BRIEF DESCRIPTION OF THE DRAWINGS

In the drawings, which are discussed below, one or more preferred embodiments are illustrated, with the same reference numerals referring to the same pieces of the invention throughout the drawings. It is understood that the invention is not limited to the preferred embodiments depicted in the drawings herein.

FIG. 1 is a top down view of a combined modulator and inverter according to an embodiment of the present invention.

FIG. 2 shows a front view of the combined modulator and inverter of FIG. 1.

FIG. 3 shows a rear view of the combined modulator and inverter of FIG. 1.

FIG. 4 shows a side view of the combined modulator and inverter of FIG. 1.

FIG. 5 shows a side view of the combined modulator and inverter of FIG. 1.

FIG. 6 shows a bottom up view of the combined modulator and inverter of FIG. 1.

FIG. 7 shows a top down view of the combined modulator and inverter of FIG. 1.

FIG. 8 is a schematic of a circuit used to control the functioning of the combined modulator and inverter shown in FIGS. 1-7 according to an embodiment of the present invention.

FIG. 9 is a flow chart of the operation of the circuit of FIG. 8, according to one embodiment of the present invention.

FIG. 10 is a schematic of an alternative circuit that can be used to control the combined modulator and inverter of FIGS. 1-7 according to an embodiment of the present invention.

FIG. 11 shows a circuit diagram of the power inverter and the USB charger.

FIG. 12 shows a circuit diagram of the transmitter circuit.

### DETAILED DESCRIPTION OF THE INVENTION

While the specification concludes with claims particularly pointing out and distinctly claiming the subject matter that is regarded as the invention, the invention will now be further described by reference to the following detailed description of preferred embodiments taken in conjunction with the above-described accompanying drawings.

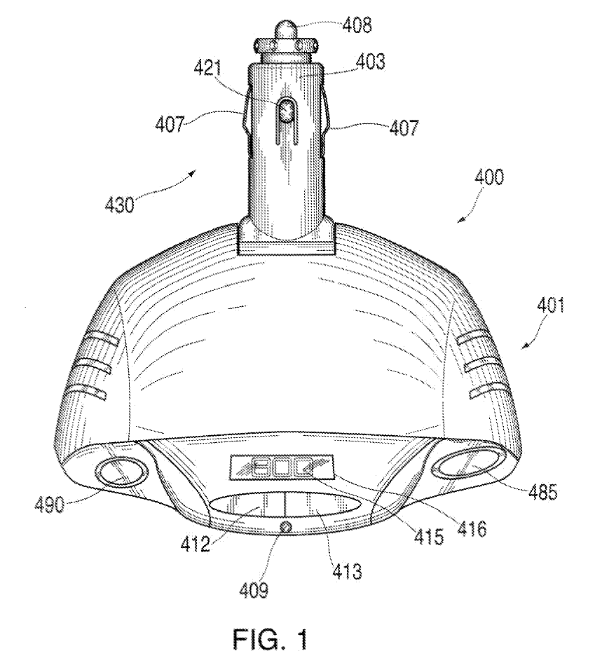

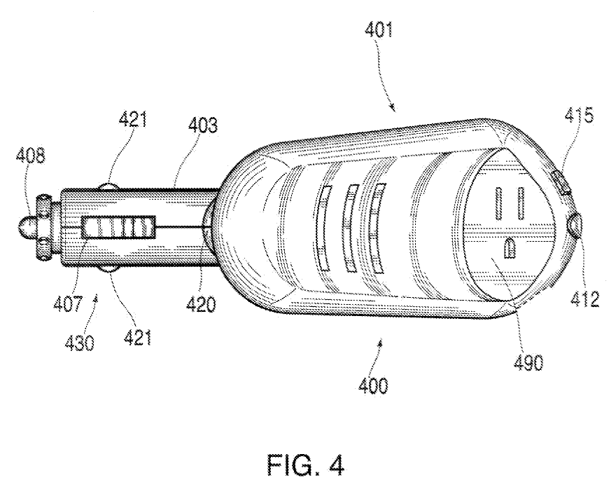

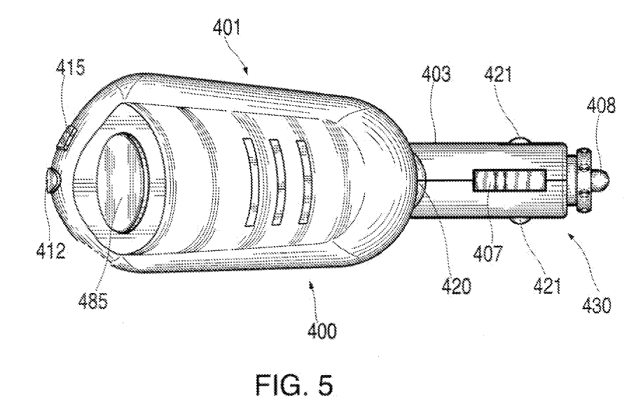

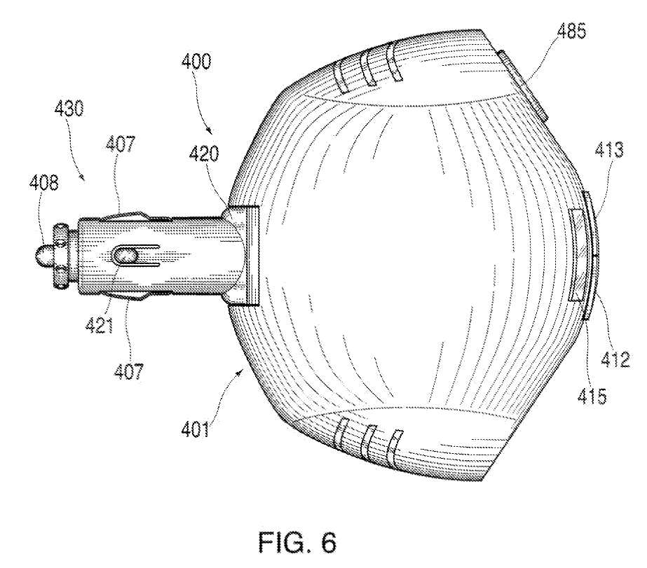

Referring to FIGS. 1-7, a combined modulator and inverter 400 (hereinafter “combined modulator/inverter”) is illustrated according to a first embodiment of the present invention. The combined modulator/inverter 400 comprises a housing 401. The housing 401 is preferably made of plastic, but can be constructed of any material desired, including without limitation metal, alloys, polymers, wood, etc. The housing 401 can be a multi-piece construction or a single piece construction. Housing 401 can be formed by any suitable process known in the art, including without limitation, an injection molding process, an extruding process, a machining process, etc. In multiple-piece construction embodiments of housing 401, the component pieces can be connected by any means know in the art, including without limitation, heat welding, adhesive, fasteners, snap-fit, etc. The housing 401 has a generally bulbous shape.

Connected to the housing 401 is the tubular body portion 403. The tubular body portion 403 is preferably cylindrical in shape and has a circular cross-sectional profile that forms part of the power plug 430. Preferably, the circular cross-sectional profile of the tubular body portion 403 is sized so that it has a diameter that is slightly smaller than the diameter of a standard cigarette lighter socket commonly incorporated into automobiles. In one embodiment, the diameter of the tubular body portion 403 is within the range of one-half inch to one inch, and more preferably about three-quarters of an inch. The length of the tubular body portion 403 is preferably sized to be at least as long as the depth of standard cigarette lighter sockets that are commonly incorporated into automobiles, most preferably within the range of 1-3 inches.

The housing 401 is pivotally connected to the tubular body portion 403 via pivot joint 420. The pivot joint 420 provides the ability for the housing 401 to be pivotable between multiple positions. As a result, when the tubular body portion 403 is inserted, into a cigarette lighter socket during operation, the housing 401 can be pivoted so that the control panel, which is comprised of buttons 412 and 415, is conveniently accessible and visible to the user, irrespective of the orientation of the socket.

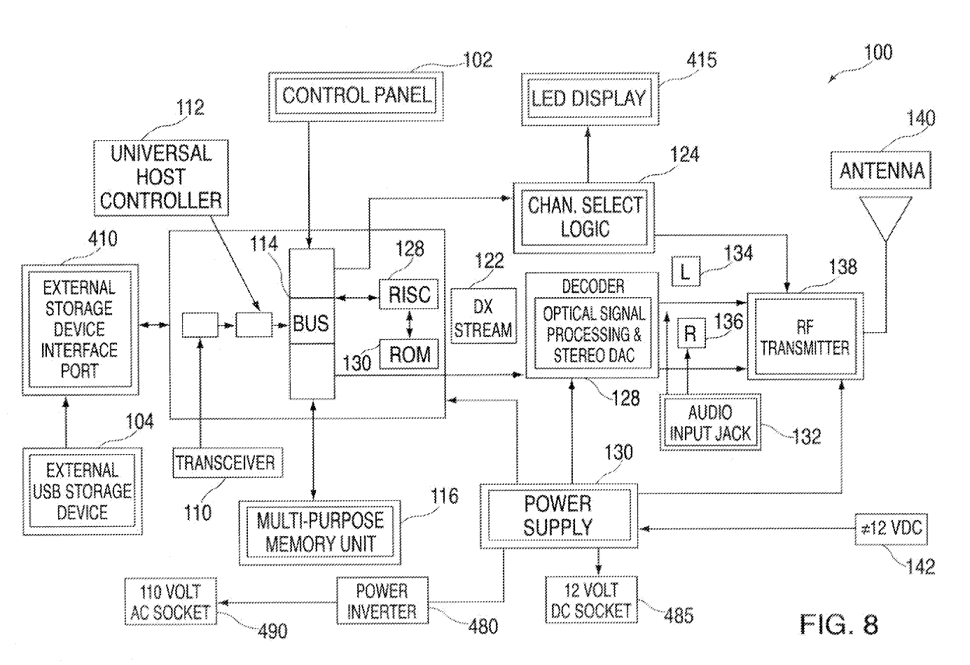

The Electrical contact leads 407, 408 are located on and protrude from the tubular body portion 403. The electrical leads 407, 408 are in operable connection with the internal circuit 100, shown in FIG. 8. As a result, a socket power inverter is formed that is electrically and sizably compatible with a standard 12 Volt cigarette lighter socket. The depressible tabs 421 are located on the top and bottom of the tubular body portion 403 of the housing 401. The depressible tabs 421 protrude from the tubular body portion 403 to help keep the combined modulator/inverter 400 in a tight fit position when positioned in a cigarette lighter socket of a vehicle. The circuitry and functioning of the combined modulator/inverter 400 will be discussed in greater detail below with describing FIGS. 8-12.

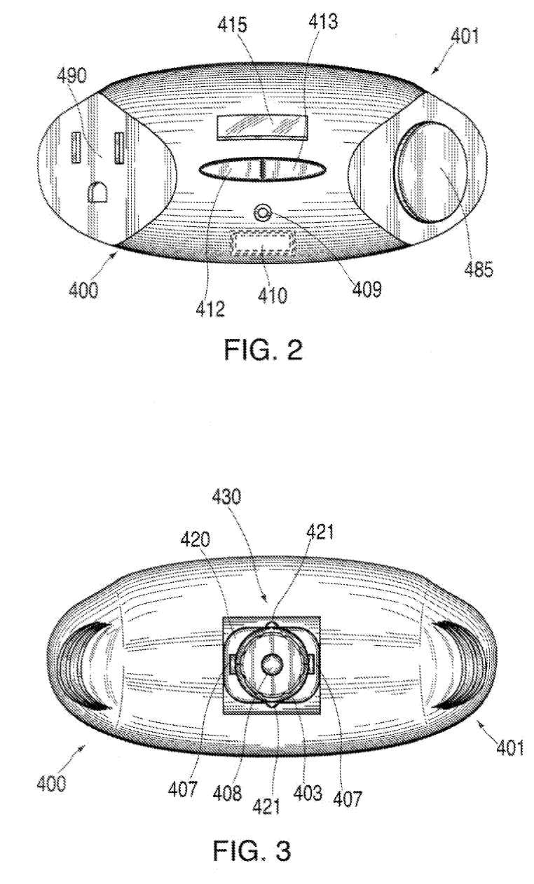

Still referring to FIGS. 1-2, the combined modulator/inverter 400 further comprises a female port 409, in the form of an audio input jack port on the front face of the housing 401. The female port 409 is accessible from the exterior of the housing 401 so as to be capable of receiving the male end of an audio cable whose other end is typically operably connected headphones. However the other end may be operably connected to the audio output port of an electronic device, such as a headphone port, or the like, of an MP3 player or CD player. Other electronic devices can be operably connected if desired, such as a laptop computer, a cell phone, a personal data assistant, video game player, portable TV, DVD player, a portable email apparatus, etc. Moreover, the female port 409 is not limited to an audio input jack port but can be any type of port desired.

Additionally, located on the front face of the housing 401 are control panel features for receiving user input commands. The control panel comprises a “back” button 412, and a “forward” button 413. These buttons interface with the control panel circuit 102 and can serve to control a variety of operations that can be performed with the combined modulator/inverter 400. The LED 415 operates as a display for indicating the channel selected. Channels may be preset for ease of usage. All of the components of the control panel are electrically and operably coupled to the internal circuit 100 through control panel circuit 102. Additional functions such as “stop/play,” and “pause” may be added in alternative embodiments. The control panel may permit the user to set the frequency at which the transmitter 138, shown in FIG. 8 will transmit the radio frequency signals containing the audio content. The frequency/channel that is currently selected will be indicated by illumination of the proper LED 415 on the channel display panel 416.

In alternative embodiments, less or more control buttons may be present on the control panel and operably coupled to the circuit. For example, the channel display panel 416 can be removed. In such an embodiment, the manufacturer may preset the frequency to which the modulator is set so that a user cannot change the frequency. Moreover, certain features can be combined on the control panel and/or the ability to select different modes, e.g. audio modes or the desired port to read, can be added.

The combined modulator/inverter 400 further comprises a 110 V AC socket 490 and a 12 volt DC socket 485. The 110 V socket 490 is connected to power inverter 480 that is contained within housing 401 and is operably coupled to the circuit schematic of FIG. 8. 110 V socket 490 performs the function of a power socket and is able to receive AC devices. The 110V socket 490 permits the usage of devices that use AC electricity while in vehicles such as cars, RVs and boats. The 12 volt DC socket 485 is capable of receiving devices that utilize 12 volt DC electricity. The 12 volt DC socket 485 is operably coupled to the circuit of FIG. 8 and permits a user to simultaneously power more than one DC device from a vehicle's energy supply.

Referring now to FIG. 2, a front view of the combined modulator/inverter 400 is shown. The combined modulator/inverter 400 comprises an interface port 410 for receiving an external memory device. While the interface port 410 is used in one embodiment of the invention, it is to be understood that it is possible to use the combined modulator/inverter 400 without an interface port 410 by connecting an audio device through the female port 409. In the illustrated embodiment, the interface port 410 is a USB slot for receiving a USB memory device, such as a USB memory stick, and MP3 player, a USB key, etc. The invention, however, is not so limited and the interface port 410 can take on a variety of embodiments, including without limitation a drive or port necessary to operably receive any kind of external storage devices, such as flash disks or drives, flash cards, secure data flash cards, pen drives, CDs, magnetic disks, mini-disks, magneto-optical disks, SRAM, E²PROM, DVDs, multimedia memory cards, secure digital cards, memory sticks, CompactFlash cards, SecureDigital cards and SmartMedia cards. Additionally, the interface port 410 may be a IEEE 1394 port (commonly known as a firewire port), or use some other type of interface standard. It is also possible to have more than one type of interface port 410.

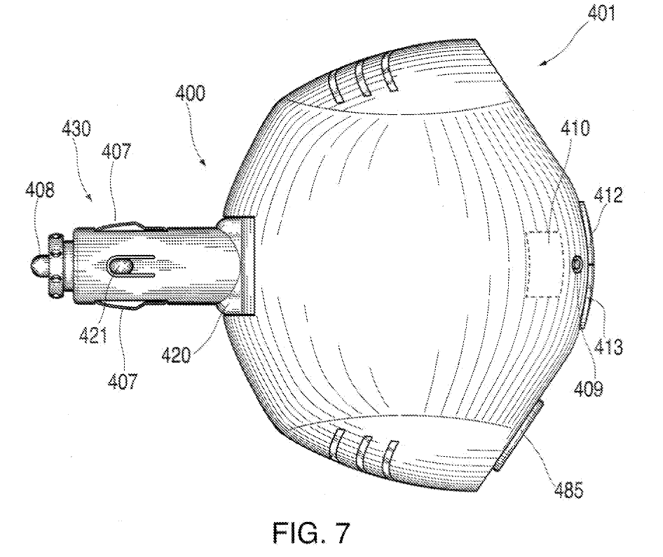

Referring to FIGS. 2 and 7, the interface port 410 is located on, and accessible from, the bottom of the housing 401. In other embodiments, the interface port 410 may be located elsewhere on the housing 401. The interface port 410 is operably coupled to the internal circuit 100 shown in FIG. 8 so that data files stored on an external memory device that is operably connected to the interface port 410 can be retrieved, decoded, processed, and/or transmitted to a car stereo receiver. This will be discussed in greater detail below with respect to FIGS. 8-12.

Referring now to FIGS. 8-12, the combined modulator/inverter 400 can be used to transmit audio content, such as that stored in MP3 files, to an automobile stereo for sound output. The exact functioning of the combined modulator/inverter 400 will be dictated by the user preferences/inputs and the type of external device on which the audio files are stored, e.g., whether the audio files are stored on a simple memory medium or on the internal memory drive a portable audio player. Either way, once the audio signal is converted into a corresponding radio frequency signal, the transmitter 138 in the housing 401 of the combined modulator/inverter 400 generates and transmits the radio frequency signal, such, as an FM signal. This RF signal is transmitted to a FM receiver located at the vehicle stereo. The FM receiver of the vehicle stereo in turn is operably coupled to the automobile's speaker system. The FM receiver of the car stereo system can be hardwired or wirelessly coupled to the automobile's speaker system. Either way, the audio content stored on an external memory device is transmitted by the combined modulator/inverter 400 and is received by the FM receiver where it outputted as audible sound by the speakers operably connected to the FM receiver.

The transmitter 138 can transmit audio content played through the combined modulator/inverter 400 within a range of FM frequencies. The transmitter 138 may be of any suitable type, and operates to transmit audio content to an FM receiver in the vicinity of the combined modulator/inverter 400. The FM transmitter 138 may for example be provided having a tuning frequency in the FM band of 87-107 megahertz (MHz) and a transmission range up to 6 feet or more. Stereo transmitters of this type are commercially available and are of appropriate size for incorporation in the combined modulator/inverter 400. If desired, the transmitter 138 may simply transmit at a frequency fixed in the aforementioned 87-107 MHz band or the transmitter 138 may be tunable to select a specific frequency within such spectrum.

In operation, the FM receiver of the stereo system receives the transmitted audio from the combined modulator/inverter 400. The FM receiver is able to transmit the audio content to the vehicular sound system, e.g., by tuning the FM receiver to the frequency of the transmitter in the combined modulator/inverter 400.

As described above, the combined modulator/inverter 400, comprises multiple input ports or jacks for a variety of audio connections, including, but not limited to, firewire, USB, RCA and/or miniplug applications. By having multiple input ports or jacks, users will not be limited to specific modulators for specific portable audio and video devices. In other words, users will be able to use one modulator for a plurality of devices. For example, an individual who owns both an MP3 player that has a USB port and a portable CD-player that has a miniplug will be able to use one modulator that accepts both types of connections. Additionally, an individual may utilize the inverter functions to use a variety of different devices. Moreover, it is possible to provide MP3 player functionality to the modulator/inverter 400 so that simple memory devices, such as USB memory sticks, that contain stored MP3 files can be used without the need for a separate MP3 player.

As discussed above, the combined modulator/inverter 400 can be set by the manufacturer or the user to utilize radio frequencies, typically on the FM or AM band. Alternatively or in addition, the combined modulator/inverter 400 can have a digital output so that it can be used with a digital tuner.

In another embodiment of the invention, the combined modulator/inverter 400, can be connected to an external storage device. Non-limiting examples of external storage devices are flash disks or drives, flash cards, secure data flash cards, pen drives, CDs, magnetic disks, mini-disks, magneto-optical disks, SRAM, E²PROM, DVDs, multimedia memory cards, secure digital cards, memory sticks, CompactFlash cards, SecureDigital cards and SmartMedia cards. As discussed above, the combined modulator/inverter 400 has a port corresponding to the external storage device's connector so that the external storage device and the modulator can be operably connected. The modulator has a processing device contained therein so that it can read a file on the external storage device. Optionally, a control module is present so that the user can choose which file to decode and transmit to the radio or digital tuner.

Referring to FIG. 8, a schematic of the circuit 100 contained within the housing of the combined modulator/inverter 400 is illustrated. All components of the circuit 100 are operably and electrically connected as needed. Those skilled in the art will appreciate the nature and location of such connections.

The circuit 100 comprises a control panel circuit 102 (which is operably connected to buttons 412 and 413), an external storage device interface port 410 and a central processing unit 108. The central processing unit (CPU) 108 is comprised of a transceiver 110, a universal host controller 112, a bus 114, a reduced instruction set computer (“RISC”) 118 and read only memory (“ROM”) 120.

The control panel circuit 102 functions to generate a signal to instruct the circuit 100 to execute at least one specific operation in response to a user input (for example, operation start/end, file selection, channel selection, etc.). The control panel circuit 102 can have a key input unit that initiates the generation of the signal. The external storage device 104 is connected to the external storage device interface port 410 and the connection functions to provide a data path for packet data transmitted to and from the external storage device 104 in response to a data request and data applied from the external storage device 104. The interface port 410 also functions to interface various data transmitted to the external storage device 104 and applied to the external storage device 104 to comply with communication standards.

Still referring to FIG. 8, the bus 114 is electrically connected to the control panel circuit 102, the universal host controller 112, the RISC 118, the multi-purpose flash memory 116 and the channel select logic unit 124. The CPU 108 integrally controls the respective elements of the system to perform an operation corresponding to a control signal by processing control signals received from the control panel circuit 102, requests and receives data from the external storage device 104 and instructs the received data to be applied to a specific path through the transceiver 110.

The multi-purpose flash memory 116 is interconnected with the CPU 108 via the bus 116. The RISC 118 stores an execution program for executing the operations of the circuit 100, which is programmed to execute a corresponding operation according to the instruction of the CPU 108.

The decoder unit 128 is operably connected to the CPU 108. As shown, the decoder unit 128 is capable of digital signal processing and stereo digital to analog converting. The stereo digital to analog converter (“DAC”) separates the audio into left 134 and right 136 channels. The decoder unit 128 optionally is equipped with a buffer to delay transmission speed. The decoder unit 128 functions to convert decoded digital data, to analog signals and to apply the analog signals to the radio frequency (“RF”) transmitter 138 which transmits the signals to an antenna 140. Alternatively, a digital signal converter in addition to or instead of the DAC and/or a sigma-delta converter can implement a high resolution of more than 16 bits and/or an optical signal converter can be used.

Still referring to FIG. 8, a channel select logic unit 124 is connected to the CPU 108. The channel select logic unit 124 can be either preset by the manufacturer or permit a user of the circuit 100 to determine at which radio frequency the audio signals should be sent. The LED display 415 is electrically connected to the channel select logic unit 124. The LED display 415 can also indicate whether the combined modulator/inverter 400 has power or not.

The circuit 100 is powered by a power supply unit 130 (which is formed by the electric leads 407, 408). The power supply unit 130 is connected to the CPU 108, the decoder 128, and the transmitter 138. The power supply unit 130 is also operably connected to the power inverter 480 which is connected to 110 V AC socket 490. The 12 Volt DC socket 485 is also operably connected to the power supply 130, which can be a 12 Volt socket 142. When using the sockets 490 and 485, switches may be activated within the circuit 100 in order to supply power to one socket and not to the other. The placement and usage of switches are know to those in the art. Alternatively, it may be possible to supply power to both sockets 490 and 485 simultaneously, as well as utilize the modulating function.

Although the above-described control panel circuit 102, universal host controller 112, RISC 118, and associated circuitry, have been described as being separated from each other, they may be implemented as a single chip. Also, the multi-purpose memory unit 116 may be incorporated into the control panel circuit 102 and/or RISC 118, or other unit found within the modulation.

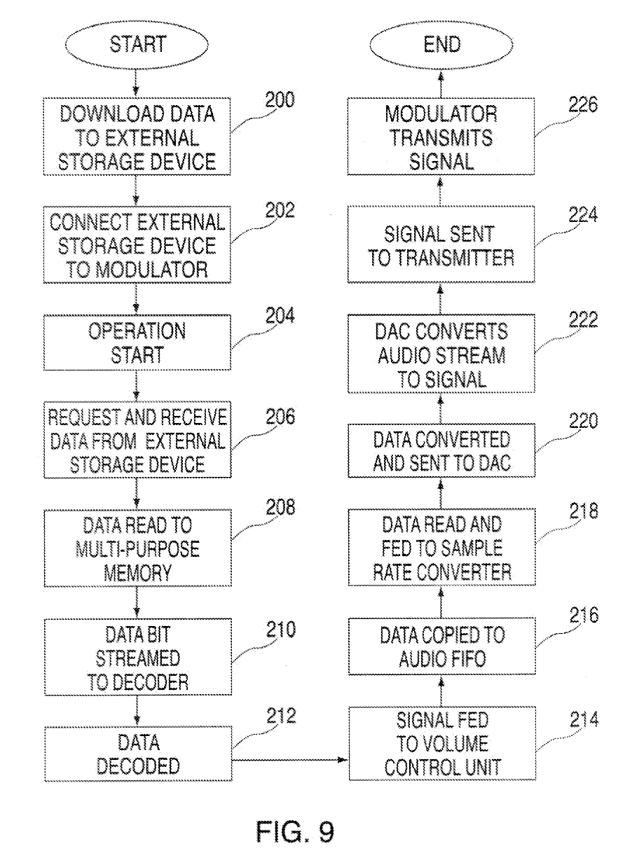

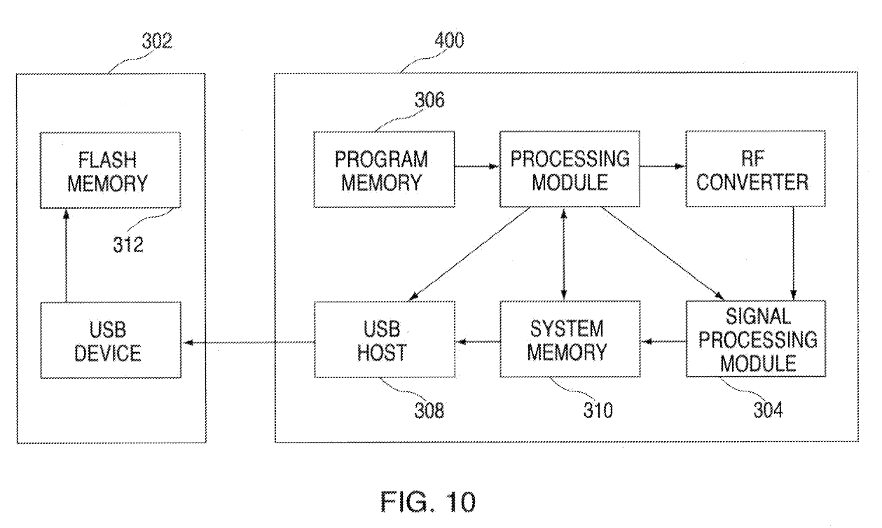

Referring now to FIG. 9, showing a flowchart of the operation of the circuit 100 of FIG. 10. Only the reproduction operation of the modulator is described herein because the other operations, including, but not limited to, music selection and music change operations, are the same as or similar to those of general MP3 or other portable audio devices.

First, at step 200 a user connects the external storage device to a PC or other device capable of downloading files to the external storage device. Next, the user disconnects the external storage device from the PC used to download or save files thereon and connects the connector of the external storage device to the combined modulator/inverter 400 at step 202. The CPU 108 determines whether the control panel circuit 102 has been activated, and if it has been activated, the CPU 108 executes the initiation mode required to initiate operations at step 204.

If the control panel circuit 102 has not been activated, the CPU 108 stands by; in an alternative embodiment, the circuit 100 automatically begins the initiation mode after detecting an external storage device is connected thereto. If the control panel circuit 102 is activated, the program written to the ROM 120 directs the RISC 118 to request data from the external storage device through the transceiver 110 and the CPU 108 receives the data at step 206. The universal host controller 112 reads the data and a built-in phase lock loop (“PLL”) provides timing to the RISC 118 and transceiver 110. An external crystal, including, but not limited to a 14.318 MHz crystal, provides the time base for the PLL. The received data is read to the multi-purpose memory 116 at step 208. The data is then applied to the decoder unit 128 via bit stream 122 at step 210. The data is decoded and, optionally, a signal is fed to a volume control unit 214. The data is copied to audio FIFO at step 216. The audio FIFO (first in and first out) holds the data, which is read by the audio interrupt and fed to a sample rate converter and an 18-bit over sampling, multi-bit, sigma-delta digital to analog converter at steps 218 and 220.

The sample rate converter converts all different samples rates to CLKI/512 and feeds the data to the DAC. At step 222, the DAC 128 converts the single digital audio stream, into a two channel, left 134 and right 136, analog signal. The analog signal is sent to the transmitter 138 and the transmitter transmits the signal at steps 224 and 226. The signal is transmitted through the antenna of a radio.

When a digital signal converter, a sigma-delta converter or an optical signal converter is used to convert the signal instead of the DAC 128, the data is sent to the corresponding converter in step 218. The DAC 128 in steps 220 and 222 is replaced by the signal converter implemented.

It should be apparent to one skilled in the art that the above-described combined modulator/inverter 400, and its circuit 100, can act as a player for MP3, WAV, WMA, RA, VOC, APE, CDA, AIF and/or any other audio files.

Turning now to FIG. 10, another embodiment of the internal construction and operation of the combined modulator/inverter 400 is shown that can be used in combination with an external storage device 302 having a USB connector. In the combined modulator/inverter 400, a signal processing module 304 may perform an encoding operation using a certain signal processing method, including, but not limited to, MPEG-1, MPEG-2, MPEG-3, MPEG4, Audio Layer 3, a TVF format or an OGG format. The signal processing module 304 outputs data by encoding input signals transmitted from a certain information source using the signal processing method, and constructs a file by arranging the encoded data in a certain file format. The signal format used to perform the decoding operation may be identical to or different from the format used to perform the encoding operation. The combined modulator/inverter is not limited to a specific signal formal.

The file constructed by the combined modulator/inverter 400 is positioned on the system memory 306. If the external storage device 302 cannot be accessed when the file is constructed, waiting is performed and the media file is copied to the external storage device through a USB host 308 when the external storage device 302 can be accessed. If the external storage device 302 can be accessed when the media file is constructed, the media file is copied from the system memory 310 to the external storage device 302.

Still referring to FIG. 10, when outputting data by encoding input signals transmitted from a certain information source using the signal processing method and constructing a media file by arranging the encoded media data in a certain file format, a media file may be constructed by integrating the data that are processed until the amount of data reaches a first critical value and to copy the constructed file to flash memory. In this scenario, the system memory 310 may be constructed to temporarily store a plurality of media files, and a second critical value may be set to the capacity of media files that can be accommodated in the system memory 310. When the size of files reaches the second critical value, the files existing in the system memory 310 may be copied to the external storage device 302. The copying of files to the external storage device 302 may be performed in a background fashion with respect to the operation of encoding the data.

Several different methods exist to power the combined modulator/inverter 400 with electricity. One method Is to have a cord connected to the modulator that can plug into an electrical outlet. Another method is to have the cord plug into a 12-volt socket in an automobile. A third method is to have the combined modulator/inverter 400 be battery-powered. Alternatively, the modulator can be hard-wired in an automobile. The combined modulator/inverter 400 can incorporate a battery charging mechanism so that when a portable device with a rechargeable battery is connected to the combined modulator/inverter 400, the rechargeable battery can be charged.

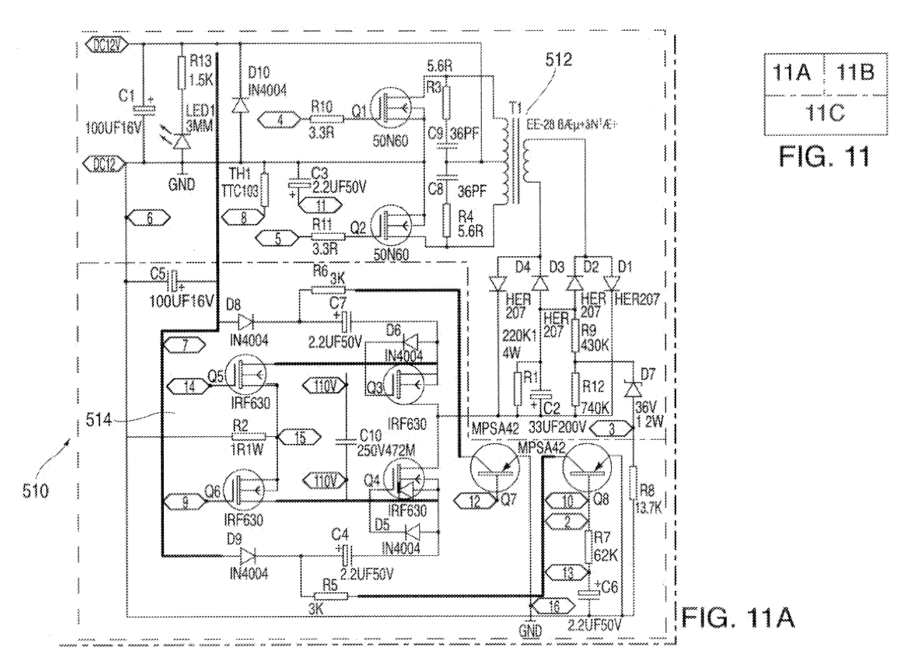

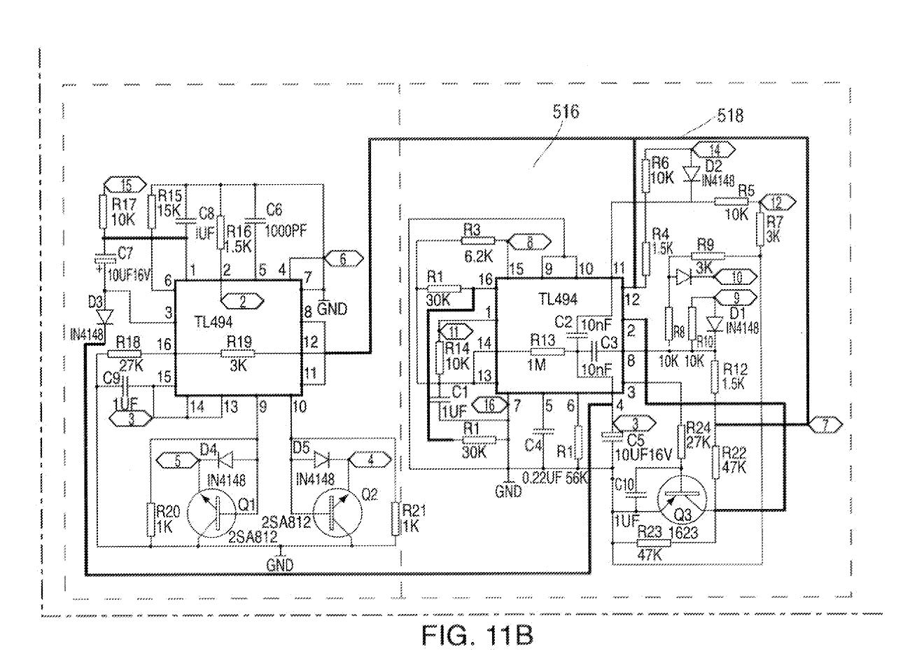

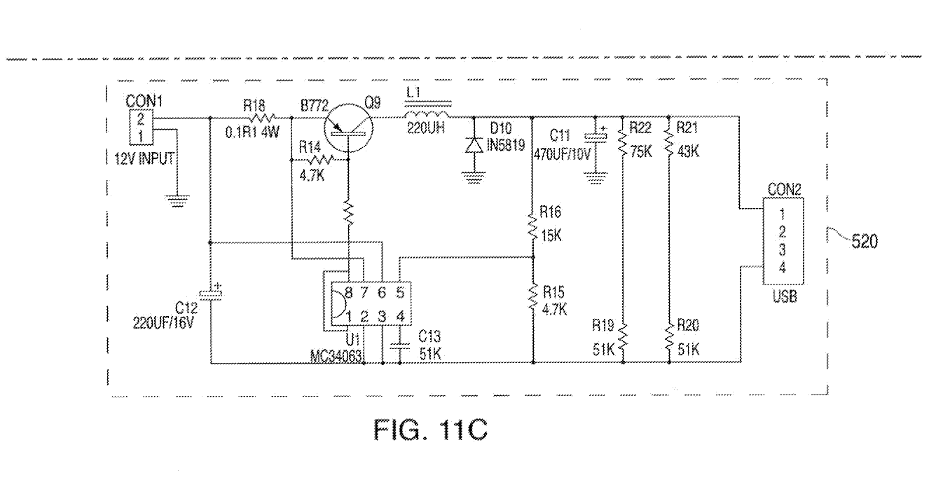

Now turning to FIG. 11, a circuit diagram of an exemplary circuit 510 for use in the power inverter 480 and the USB charger circuit 520 which is associated therewith is shown. The 110 Volt AC power converter circuit 510 has a high frequency controller circuit 516 composed of a pulse width modulator and associated components that generate a high frequency pulse train. The high frequency pulse train is fed to a switching power supply circuit 512. Power supply circuit 512 is composed of MOSFET switching transistors, a step up transformer, a plurality of diodes which form a bridge rectifier, and a number of filter capacitors. A second controller 518 is used to generate 60 Hz output pulses that drive the power output circuit 514. The frequency of the output pulses may vary depending upon the needs of the system. The power output circuit 514 consists of MOSFET switching transistors and associated components to supply a modified sine wave to the 110 Volt output socket 490 on the front panel of the modulator/inverter 400.

The USB charger circuit 529 is designed for recharging the batteries in devices, such as an iPod, iPod Shuffle. iPod Nano, USB Hard Drives, and other USB powered devices. The circuitry consists of 12 Volt DC input from the vehicle's power port. An integrated circuit converts 12 Volt DC to +5 Volt DC. A power transistor acts as a series current regulator at 1.5 Amps. Associated components provide filtering and voltage dividing functions.

The transmitter of the combined modulator/inverter 400 is now described with respect to FM frequencies. As stated previously, alternative embodiments of the transmitter have the radio frequency be on the AM band or have a digital output so that the combined modulator/inverter 400 can be used with a digital tuner in addition to or in lieu of the FM transmitter. Any of the different types of transmitters, i.e., FM, AM or digital transmitter, may be present individually or together.

The FM transmitter transmits audio played through the audio device or external storage device connected to the combined modulator/inverter 400 to a range of FM frequencies, enabling FM reception of audio music signals that then can be played through an FM receiver, such as an FM radio receiver in a vehicle, an FM radio in proximity to the modulator and otherwise for extended area broadcast of the audio files. When used in a vehicle, the FM transmitter transmits the audio to the FM receiver in the vehicle, enabling the acoustic system of the vehicle to be employed for broadcast of the audio to the interior passenger compartment of the vehicle.

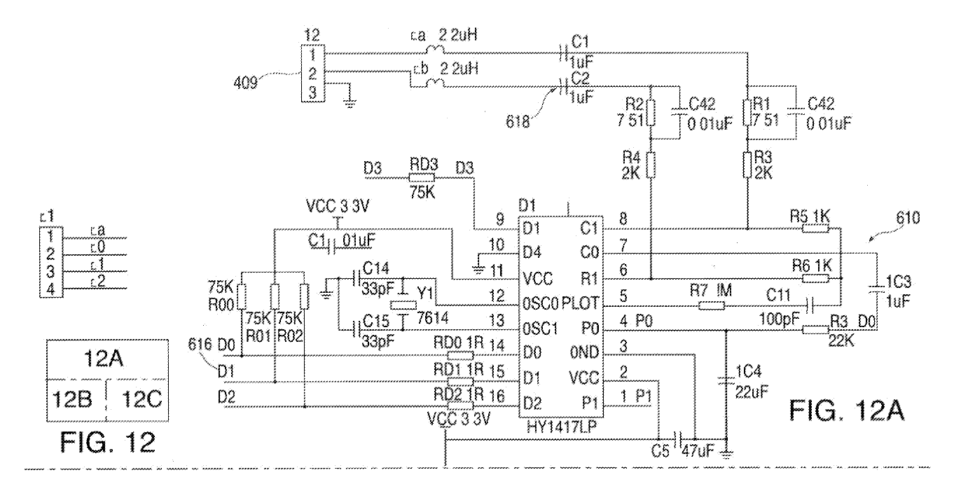

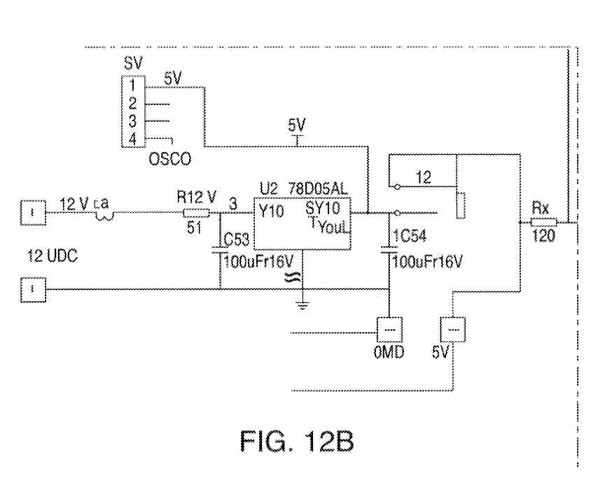

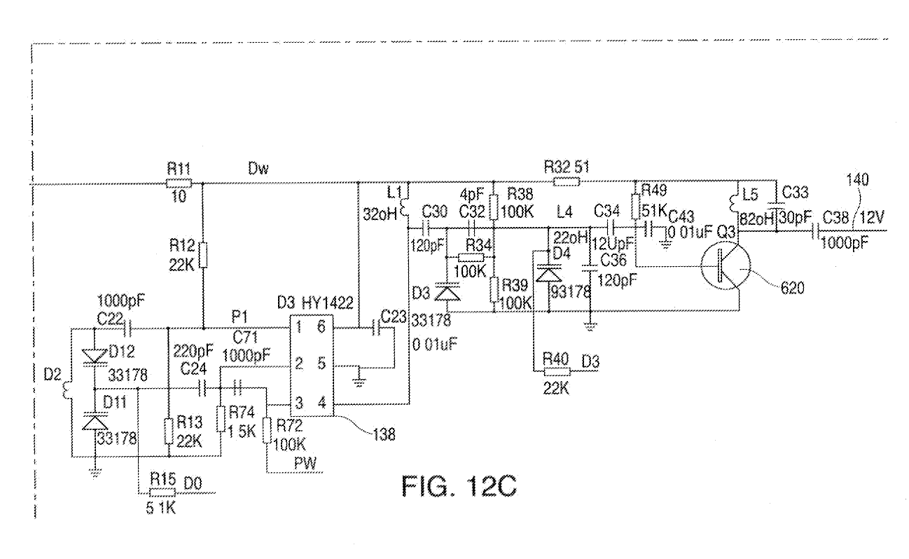

FIG. 12 shows a circuit diagram of a transmitter circuit 610. As discussed above, FM transmitter section of the modulator/inverter 400 has an interface port 410 on the front panel for connecting to external devices like DVD/CD players, MP3 players, portable cassette players, & portable AM/FM radios. It may also be possible to connect these devices through female port 409. The interface port 410 may also use ON/OFF switch 614 for FM transmitter 138 in order to activate the device. An FM Multiplexer Integrated circuit 618 creates a composite audio signal for modulating the FM transmitter. Associated components provide audio contouring and filtering. Digital Frequency setting circuitry 616 is provided for generating one of 16 possible frequencies. It is to be understood that more setting circuitry 616 may be provided should it be needed. The transmitter circuit 610 uses an integrated circuit and associated components to form a frequency modulated transmitter controlled by the phased locked loop. The antenna 140 for the FM transmitter consists of RF output being fed through a coupling capacitor to the 12 V DC input power plug. A voltage regulator 612, consisting of an integrated circuit and associated components, provides regulated voltages to the transmitter circuitry 610.

The transmitter circuit 610 is preferably shielded from the magnetic field generated from the high frequency switching power supply transformer and MOSFET switching transistors from switching power supply circuit 512. There are a variety of ways that the transmitter circuit 610 can be shielded. One way that transmitter circuit 610 can be shielded is by placing the printed circuit board (PCB) of the transmitter circuit 610 at right angles, or orthogonally, to the PCB of the power supply circuit 512. Another way of shielding the transmitter circuit 610 is by grounding the backplane of the PCB of the transmitter circuit 610 to the PCB of the power supply circuit 512. Another way of providing shielding is to surround the PCB of the transmitter circuit 610 with an aluminum case that is grounded to the PCB of the power supply circuit 512. Another method is to have the audio input cable shielded in order to prevent stray magnetic fields from entering the FM transmitter through the female port 409, alternatively the area surrounding the female port 409 may be shielded in some matter using by placing material that shields from electro-magnetic waves there. It is to be understood that these methods may be used separately or in combination. Moreover, those skilled in the art will appreciate that other shielding techniques can be utilized and are intended to be within the scope of this invention.

It is to be understood, however, that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meaning of the terms in which the appended claims are expressed.

What is claimed is:

1. A combined modulator and power inverter apparatus comprising:
a power plug for operable insertion into a cigarette lighter power receptacle of an automobile;
a housing comprising a port adapted to operably receive an external electronic device, a direct current power receptacle, an alternating current power receptacle and a radio frequency transmitter;
a circuit positioned within the housing, the circuit operably connected to the power plug, the port, the direct current power receptacle, the alternating current power receptacle and the radio frequency transmitter; and
the circuit adapted to (i) convert audio data signals received by the port into corresponding radio frequency signals; (ii) transmit the corresponding radio frequency signals to a receiver of the automobile via the radio frequency transmitter; (iii) supply direct current power from the power plug to the direct current receptacle; and (iv) convert direct current power from the power plug into alternating current power and supply the alternating current power to the alternating current receptacle.

2. The apparatus of claim 1 wherein the conversion of audio data signals into corresponding radio frequency signals and the transmission of the corresponding radio frequency signals is performed by a modulation subcircuit, the apparatus further comprising means for shielding the modulation subcircuit from electromagnetic interference generated by the circuit.

3. The apparatus of claim 1 wherein the housing comprises a tubular portion and a head portion pivotally connected to the tubular portion, wherein the tubular portion comprises the power plug and the head portion comprising the port, the direct current power receptacle, the alternating current power receptacle and the radio frequency transmitter.

4. The apparatus of claim 1 wherein the direct current power receptacle is a cigarette lighter socket receptacle.

5. The apparatus of claim 1 further comprising means for shielding the radio frequency transmitter from electromagnetic interference generated by the circuit.

6. The apparatus of claim 1 further comprising means for selecting one of a plurality of frequencies at which the corresponding radio frequency signals are transmitted by the radio frequency transmitter.

7. The apparatus of claim 6 wherein frequency selection means comprises a control panel on the housing and a display device for displaying the selected frequency.

8. A combined modulator and power inverter apparatus comprising;
a power plug for operable insertion into a cigarette lighter power receptacle of an automobile; a housing comprising a port adapted to operably receive an external electronic device, a direct current power receptacle, an alternating current power receptacle and a radio frequency transmitter;
a circuit positioned within the housing, the circuit operably connected to the power plug, the port, the direct current power receptacle, the alternating current power receptacle and the radio frequency transmitter;
the circuit adapted to (i) convert audio data signals received by the port into corresponding radio frequency signals; (ii) transmit the corresponding radio frequency signals to a receiver of the automobile via the radio frequency transmitter; (iii) supply direct current power from the power plug to the direct current receptacle; and (iv) convert direct current power from the power plug into alternating current power and supply the alternating current power to the alternating current receptacle; and
means for shielding the radio frequency transmitter from electromagnetic interference generated by the circuit.

9. The apparatus of claim 8 wherein the conversion of audio data signals into corresponding radio frequency signals and the transmission of the corresponding radio frequency signals is performed by a modulation subcircuit, the apparatus further comprising means for shielding the modulation subcircuit from electromagnetic interference generated by the circuit.

10. The apparatus of claim 8 wherein the housing comprises a tubular portion and a head portion pivotally connected to the tubular portion, wherein the tubular portion comprises the power plug and the head portion comprising the port, the direct current power receptacle, the alternating current power receptacle and the radio frequency transmitter.

11. The apparatus of claim 8 wherein the direct current power receptacle is a cigarette lighter socket receptacle.

12. The apparatus of claim 8 further comprising means for selecting one of a plurality of frequencies at which the corresponding radio frequency signals are transmitted by the radio frequency transmitter.

13. The apparatus of claim 12 wherein frequency selection means comprises a control panel on the housing and a display device for displaying the selected frequency.
